(19) United States
(12) Patent Application Publication
(10) Pub. No.: US 2026/0101702 A1
(43) Pub. Date: Apr. 9, 2026

(54) BUFFER CHAMBER AND SUBSTRATE PROCESSING APPARATUS INCLUDING THE SAME

(71) Applicant: SEMES CO., LTD., Cheonan-si (KR)

(72) Inventors: Sang Hyeop LEE, Hwaseong-si (KR); Hee Chan KIM, Hwaseong-si (KR); Na Hyun LEE, Ansan-si (KR); Myung Jin LEE, Hwaseong-si (KR); Min Seong KIM, Hwaseong-si (KR); Sang Oh KIM, Seoul (KR)

(73) Assignee: SEMES CO., LTD., Cheonan-si (KR)

(21) Appl. No.: 19/346,669

(22) Filed: Oct. 1, 2025

(30) Foreign Application Priority Data
Oct. 7, 2024 (KR) 10-2024-0135992

(51) Int. Cl. H01L 21/67; H01L 21/677

(52) U.S. Cl. CPC H10P 72/0464; H10P 72/0456; H10P 72/3302; H10P 72/3402

(57) ABSTRACT

Provided is an apparatus of processing a substrate. The apparatus includes: a first module; a second module; and a buffer chamber disposed between the first module and the second module and temporarily storing a substrate transferred between the first module and the second module. The transfer chamber includes: a housing providing an inner space; a support unit including a plurality of support plates supporting the substrate in the inner space; a plurality of shower plates having an injection hole for injecting the gas to the substrate supported by the support unit; and a gas supply unit for supplying the gas to the shower plate, and the support plates are provided in a stacked structure, and each of the shower plates is provided to correspond to each of the support plates.

### CROSS-REFERENCE TO RELATED APPLICATION

This application claims priority to and the benefit of Korean Patent Application No. 10-2024-0135992 filed in the Korean Intellectual Property Office on Oct. 7, 2024, the entire contents of which are incorporated herein by reference.

### TECHNICAL FIELD

The present invention relates to a substrate processing apparatus, and more particularly, to a substrate processing apparatus including a buffer chamber.

### BACKGROUND ART

In order to manufacture a semiconductor device, various processes, such as cleaning, deposition, photolithography, etching, and ion implantation, are performed. In recent years, with the high integration of semiconductor devices, miniaturization of resist patterns is required. In order to realize the miniaturization of resist patterns, an exposure treatment using extreme ultraviolet (EUV light) has been proposed. In the exposure treatment using EUV light, a resist containing a metal (hereinafter referred to as a ‘metal-containing resist’) is used. The metal-containing resist provides high resolution, high selectivity, and high sensitivity to EUV light, so it is very suitable for EUV exposure processes. However, this resist has the disadvantage of being vulnerable to moisture. When the metal-containing resist comes into contact with moisture, pattern deterioration and particle generation may occur. Therefore, the atmosphere around the substrate needs to be controlled to be low humidity.

To this end, the substrate to which the metal-containing resist is applied waits for a predetermined time in the buffer chamber before and after each process. The buffer chamber has a sealed structure, and may control the inner atmosphere, and supplies low-humidity gas to block contact between the substrate and moisture. However, when low-humidity gas is supplied to the buffer chamber, if the gas is not uniformly supplied to each substrate, the uniformity within the substrate surface and the uniformity between the substrates may deteriorate.

### SUMMARY OF THE INVENTION

The present invention has been made in an effort to provide a buffer chamber capable of preventing defects and particles from being generated in a metal-containing resist applied on a substrate and a substrate processing apparatus including the same.

The present invention has also been made in an effort to provide a buffer chamber capable of preventing interference with robots entering a buffer chamber even when a shower plate is provided to each support plate, and a substrate processing apparatus including the same.

The present invention has also been made in an effort to provide a buffer chamber capable of uniformly forming and maintaining an atmosphere on a substrate supported in a buffer chamber at low humidity, and a substrate processing apparatus including the same.

The present invention has also been made in an effort to provide a buffer chamber capable of increasing the efficiency of a space occupied by the buffer chamber, and a substrate processing apparatus including the same.

The objectives of the present disclosure are not limited thereto and other objectives not stated herein may be clearly understood by those skilled in the art from the following description.

An exemplary embodiment of the present disclosure, an apparatus for processing a substrate, the apparatus comprising: a first module; a second module; and a buffer chamber disposed between the first module and the second module and temporarily storing a substrate transferred between the first module and the second module, wherein the transfer chamber includes: a housing providing an inner space; a support unit including a plurality of support plates supporting the substrate in the inner space; a plurality of shower plates having an injection hole for injecting the gas to the substrate supported by the support unit; and a gas supply unit for supplying the gas to the shower plate, and the support plates are provided in a stacked structure, and each of the shower plates may be provided to correspond to each of the support plates.

According to the exemplary embodiment of the present invention, wherein the first module is an index module, the second module is a processing module, and the index module includes: a load port on which a container in which the substrate is accommodated is placed; and an index robot for transferring the substrate from the container placed on the load port to the processing module, and accommodating the substrate completely processed in the processing module in the container placed on the load port, and the processing module may includes: a process chamber for processing the substrate; and a transfer chamber including a transfer robot that loads the substrate into the process chamber or unloads a substrate from the process chamber.

According to the exemplary embodiment of the present invention, wherein the shower plate includes: an injection part for injecting the gas into the substrate supported on the support plate; and a connection part connecting the gas supply unit and the injection part, and the connection part may be provided on the side of the injection part.

According to the exemplary embodiment of the present invention, wherein the shower plate further includes a guide member provided inside the connection part and the injection part, and the guide member may guides flow of the gas so that the gas injected into the connection part is uniformly diffused toward the injection part.

According to the exemplary embodiment of the present invention, wherein the guide member includes a plurality of guide pins, and the guide pins are arranged to be spaced apart from each other, and may be combined with each other to form a concentric circle.

According to the exemplary embodiment of the present invention, wherein the guide member includes a plurality of guide walls, and the guide walls are arranged to be spaced apart from each other, and may be combined with each other to form a concentric circle.

According to the exemplary embodiment of the present invention, wherein the shower plate includes a first shower plate and a second shower plate, the support plate includes a first support plate and a second support plate, the first support plate, the first shower plate, the second support plate, and the second shower plate are stacked in this order, and the first shower plate may be provided to be adjacent to a lower portion of the second support plate.

According to the exemplary embodiment of the present invention, wherein a diameter of the injection part may be smaller than a diameter of the support plate.

According to the exemplary embodiment of the present invention, wherein the injection holes are provided in plural, and among the injection holes, the injection hole in a central region of the shower plate is vertically formed, and among the injection holes, the injection hole in an edge region of the shower plate may be formed to be inclined.

According to the exemplary embodiment of the present invention, wherein the plurality of buffer chambers is provided to be stacked, the gas supply unit includes a valve that adjusts a flow rate of the gas supplied to the buffer chamber, and the apparatus may includes a controller that independently controls the valve.

According to the exemplary embodiment of the present invention, wherein the gas has a lower humidity than a surrounding atmosphere of the index robot or the transfer robot.

An exemplary embodiment of the present disclosure, a buffer chamber for temporarily storing a substrate, the buffer chamber comprising: a housing providing an inner space; a support unit including a plurality of support plates supporting a substrate in the inner space; a plurality of shower plates having a plurality of injection holes for injecting the gas to the substrate supported by the support unit; and a gas supply unit for supplying the gas to the shower plate, and the support plates are provided in a stacked structure, and each of the shower plates may be provided to correspond to each of the support plates.

According to the exemplary embodiment of the present invention, wherein the shower plate further includes: a connection part into which the gas is injected, an injection part formed to spatially communicate with the connection part; and a guide member for guiding a flow of the gas so that the gas injected into the connection part is uniformly diffused inside the injection part, the connection part is provided on a side of the injection part, and a plurality of guide members is provided inside the connection part and the injection part, and may be spaced apart from each other and combined with each other to form a concentric circle.

According to the exemplary embodiment of the present invention, wherein the shower plate includes a first shower plate and a second shower plate, the support plate includes a first support plate and a second support plate, the first support plate, the first shower plate, the second support plate, and the second shower plate are stacked in this order, and the first shower plate may be provided to be adjacent to a lower portion of the second support plate.

According to the exemplary embodiment of the present invention, wherein among the injection holes, the injection hole in a central region of the shower plate is vertically formed, and among the injection holes, the injection hole in an edge region of the shower plate may be formed to be inclined.

According to the exemplary embodiment of the present invention, wherein the plurality of shower plates is installed under the support plate, which is adjacent to an upper side, and a diameter of the injection part may be smaller than a diameter of the support plate.

According to the exemplary embodiment of the present invention, wherein the gas has a lower humidity than a surrounding atmosphere of the index robot or the transfer robot.

An exemplary embodiment of the present disclosure, an apparatus for processing a substrate, the apparatus comprising: an index module for unloading a substrate from a container in which the substrate is accommodated or loads the substrate into the container; a processing module for processing a substrate; and a buffer chamber for temporarily storing a substrate, wherein the index module includes: a load port on which the container in which the substrate is accommodated is placed; and an index robot for transferring the substrate from the container placed on the load port to the processing module, and accommodating the substrate completely processed in the processing module in the container placed on the load port, and the processing module includes: a process chamber for processing the substrate; and a transfer chamber including a transfer robot that loads the substrate into the process chamber or unloads the substrate from the process chamber, the buffer chamber includes: a housing providing an inner space; a support unit for supporting the substrate in the inner space; a plurality of shower plates having a plurality of injection holes for injecting gas to the substrate supported by the support unit; and a gas supply unit for supplying the gas to the shower plate, and the support unit includes a plurality of support plates that supports the substrate and is provided in a stacked structure, the gas has a lower humidity than a surrounding atmosphere of the index robot or the transfer robot, the shower plate is provided to correspond to each support plate, and includes: an injection part for injecting the gas into the substrate supported on the support plate; and a connection part connecting the gas supply unit and the injection part; and a plurality of guide members installed inside the connection part and the injection part and arranged to have a concentric pattern based on a center of the injection part, the connection part is provided on a side of the injection part, and a diameter of the injection part may be smaller than a diameter of the support plate.

According to the exemplary embodiment of the present invention, wherein the shower plate includes a first shower plate and a second shower plate, the support plate includes a first support plate and a second support plate, the first support plate, the first shower plate, the second support plate, and the second shower plate are stacked in this order, and the first shower plate may be provided to be adjacent to a lower portion of the second support plate.

According to the exemplary embodiment of the present invention, wherein the plurality of buffer chambers is provided to be stacked, the gas supply unit includes a valve that adjusts a flow rate of the gas supplied to the buffer chamber, and the apparatus may includes a controller that independently controls the valve.

According to the exemplary embodiment of the present invention, it is possible to prevent defects and particles from being generated in a metal-containing resist applied on a substrate.

Further, according to the exemplary embodiment of the present invention, it is possible to prevent interference with robots entering a buffer chamber even when a shower plate is provided to each support plate.

Further, according to the exemplary embodiment of the present invention, it is possible to uniformly form and maintain an atmosphere on a substrate supported in a buffer chamber at low humidity.

Further, according to the exemplary embodiment of the present invention, it is possible to increase the efficiency of a space occupied by the buffer chamber.

The objectives of the present disclosure are not limited thereto and other objectives not stated herein may be clearly understood by those skilled in the art from the following description.

Effects of the present disclosure are not limited to those described above and effects not stated above will be clearly understood to those skilled in the art from the specification and the accompanying drawings.

### BRIEF DESCRIPTION OF THE DRAWINGS

FIG. 1 is a perspective view schematically illustrating a substrate processing apparatus according to an exemplary embodiment of the present invention.

FIG. 2 is a cross-sectional view of the substrate processing apparatus illustrating a coating block or a developing block of FIG. 1.

FIG. 3 is a top plan view of the substrate processing apparatus of FIG. 1.

FIG. 4 is a diagram illustrating an example of a hand of a transfer robot of FIG. 3.

FIG. 5 is a top plan view schematically illustrating an example of a heat processing chamber of FIG. 3.

FIG. 6 is a front view of the heat processing chamber of FIG. 5.

FIG. 7 is a cross-sectional view illustrating a cross-section of a buffer chamber according to an exemplary embodiment of the present invention.

FIG. 8 is a diagram schematically illustrating a support plate and a shower plate.

FIG. 9 is a diagram schematically illustrating a support plate according to an exemplary embodiment of the present invention.

FIG. 10 is a diagram illustrating a gas supply unit according to an exemplary embodiment of the present invention.

FIG. 11 is a diagram illustrating a shape of a shower plate according to an exemplary embodiment of the present invention.

FIG. 12 is a diagram illustrating various shapes of an injection hole.

FIG. 13 is a diagram schematically illustrating a substrate processing apparatus according to another exemplary embodiment of the present invention.

FIG. 14 is a view schematically illustrating the shape of a guide member according to another exemplary embodiment of the present invention.

### DETAILED DESCRIPTION

Hereinafter, an exemplary embodiment of the present invention will be described more fully hereinafter with reference to the accompanying drawings, in which exemplary embodiments of the invention are illustrated. However, the present invention may be variously implemented and is not limited to the following exemplary embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the word “include” will be understood to imply the inclusion of stated elements but not the exclusion of any other elements. It will be appreciated that terms “including” and “having” are intended to designate the existence of characteristics, numbers, operations, operations, constituent elements, and components described in the specification or a combination thereof, and do not exclude a possibility of the existence or addition of one or more other characteristics, numbers, operations, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

Terms, such as first and second, are used for describing various constituent elements, but the constituent elements are not limited by the terms. The terms are used only to discriminate one constituent element from another constituent element. For example, without departing from the scope of the invention, a first constituent element may be named as a second constituent element, and similarly a second constituent element may be named as a first constituent element.

The present invention has been described based on the case where the facility of the present exemplary embodiment is used to perform a photolithography process on a substrate, such as a semiconductor wafer or a flat display panel, as an example.

The substrate processing apparatus of the present invention includes a plurality of modules. The substrate processing apparatus of the present invention may include a first module, a second module, and a third module. The first module, the second module, and the third module perform separate functions. The first module, the second module, and the third module may be sequentially connected. According to an example, the first module is an index module 100. The second module is a processing module 300. Further, the third module is an interface module 600. However, the present invention is not limited thereto, and in the substrate processing apparatus of the present invention, a new module may be connected or any one of a plurality of modules may be omitted. Hereinafter, with respect to an exemplary embodiment of the substrate processing apparatus of the present invention, it will be described as an example that the first module is the index module 100, the second module is the processing module 300, and the third module is the interface module 600.

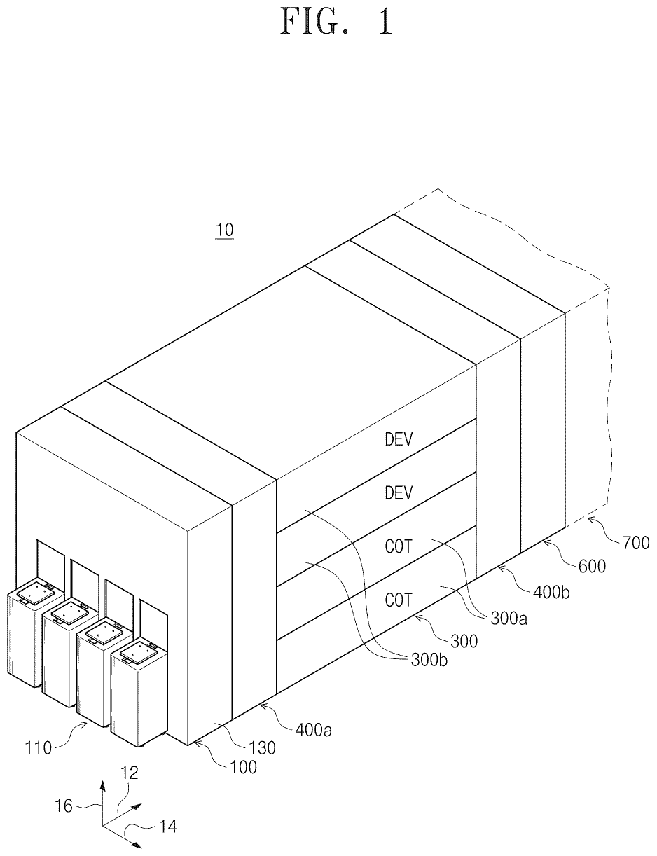

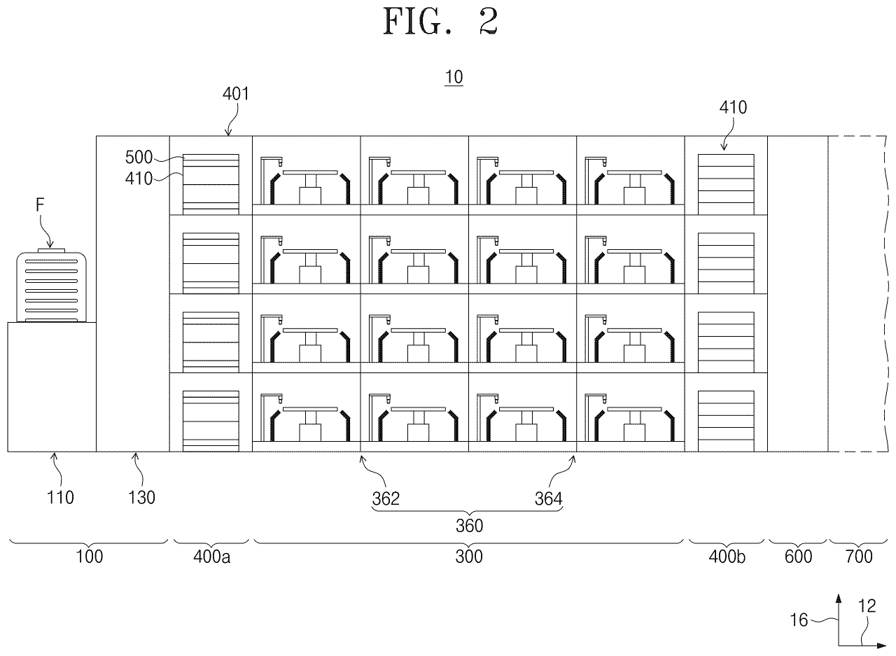

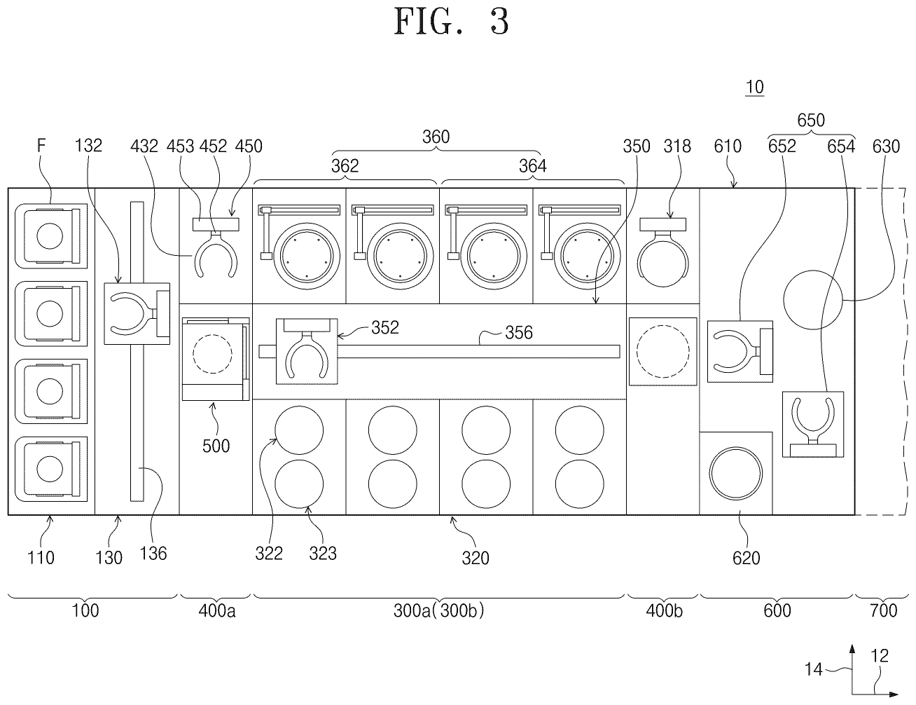

FIG. 1 is a perspective view schematically illustrating a substrate processing apparatus according to an exemplary embodiment of the present invention, FIG. 2 is a cross-sectional view of the substrate processing apparatus illustrating a coating block or a developing block of FIG. 1, and FIG. 3 is a top plan view of the substrate processing apparatus of FIG. 1.

Referring to FIGS. 1 to 3, a substrate processing apparatus 10 according to an exemplary embodiment of the present invention includes an index module 100, a processing module 300, an interface module 600, and a buffer module 400. Hereinafter, a direction in which the index module 100, the processing module 300, the buffer modules 400a and 400b, and the interface module 600 are arranged is referred to as a first direction 12, a direction perpendicular to the first direction 12 when viewed from the top is referred to as a second direction 14, and a direction perpendicular to both the first direction 12 and the second direction 14 is defined as a third direction 16.

The index module 100 transfers a substrate W from a container F in which the substrate W is accommodated to the processing module 300, and makes the substrate W, which has been completely processed, be accommodated in the container F. A longitudinal direction of the index module 100 is provided in the second direction 14. The index module 100 includes a load port 110 and an index frame 130. Based on the index frame 130, the load port 110 is located at a side opposite to the processing module 300. The containers F in which the substrates W are accommodated are placed on the load ports 110. The load ports 110 may be provided in plurality, and the plurality of load ports 110 may be disposed in the second direction 14.

As the container F, an airtight container, such as a Front Open Unified Pod (FOUP), may be used. The container F may be placed on the load port 110 by a transfer means (not illustrated), such as an overhead transfer, an overhead conveyor, or an automatic guided vehicle, or an operator.

An index robot 132 is provided to the index frame 130. A guide rail 136 of which a longitudinal direction is the second direction 14 is provided within the index frame 130, and the index robot 132 may be provided to be movable on the guide rail 136. The index robot 132 includes a hand on which the substrate W is placed, and the hand may be provided to be movable forward and backward, rotatable about the third direction 16, and movable along the third direction 16.

The processing module 300 may perform an application process and a development process on the substrate W. The processing module 300 may perform a substrate processing process by receiving the substrate W accommodated in the container F. The processing module 300 includes an applying block 300a and a developing block 300b. The applying block 300a performs an application process on the substrate W, and the developing block 300b performs a development process on the substrate W. A plurality of applying blocks 300a is provided, and they are provided to be stacked on each other. A plurality of developing blocks 300b is provided, and they are provided to be stacked on each other. According to the exemplary embodiment of FIG. 1, two applying blocks 300a and two developing blocks 300b are provided. The applying blocks 300a may be disposed under the developing blocks 300b. According to an example, the two applying blocks 300a perform the same process and may be provided in the same structure. Further, the two developing blocks 300b perform the same process and may be provided in the same structure.

Referring to FIG. 3, the applying block 300a includes a heat processing chamber 320, a transfer chamber 350, and a liquid processing chamber 360.

The heat processing chamber 320 performs a heat processing process on the substrate W. The heat processing process may include a cooling process and a heating process. The liquid processing chamber 360 forms a liquid film by supplying a liquid onto the substrate W. The liquid film may be a photoresist film or an antireflection film. According to an example, the photoresist film may be a metal-containing resist film. The transfer chamber 350 transfers the substrate W between the heat processing chamber 320, the liquid processing chamber 360, and the buffer chamber 500.

The transfer chamber 350 may be provided so that a longitudinal direction is parallel to the first direction 12. A transfer robot 352 is provided to the transfer chamber 350. The transfer robot 352 transfers the substrate between the heat processing chamber 320, the liquid processing chamber 360, and the buffer module 400. According to an example, the transfer robot 352 includes a hand on which the substrate W is placed, and the hand may be provided to be movable forward and backward, rotatable about the third direction 16, and movable along the third direction 16. A guide rail 356 whose length direction is provided parallel to the first direction 12 is provided in the transfer chamber 350, and the transfer robot 352 may be provided movable on the guide rail 356.

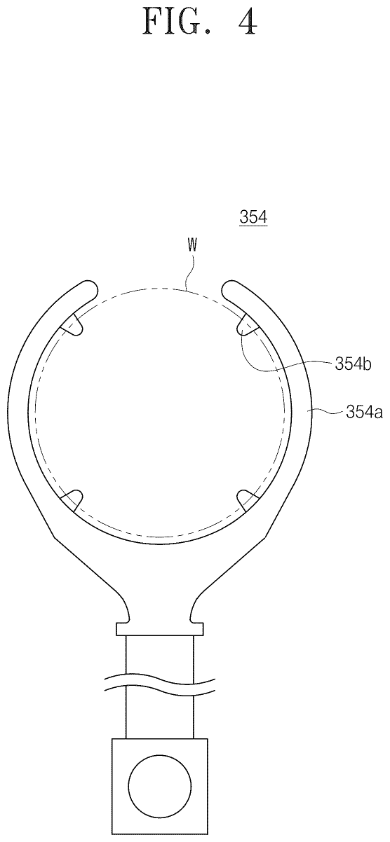

FIG. 4 is a diagram illustrating an example of the hand of the transfer robot of FIG. 3. Referring to FIG. 4, the hand 354 has a base 354a and a support protrusion 354b. The base 354a may have an annular ring shape in which a portion of the circumference is bent. The base 354a has an inner diameter larger than the diameter of the substrate W. The support protrusion 354b extends inward from the base 354a. A plurality of support protrusions 354b is provided and supports an edge region of the substrate W. According to an example, four support protrusions 354b may be provided at equal intervals.

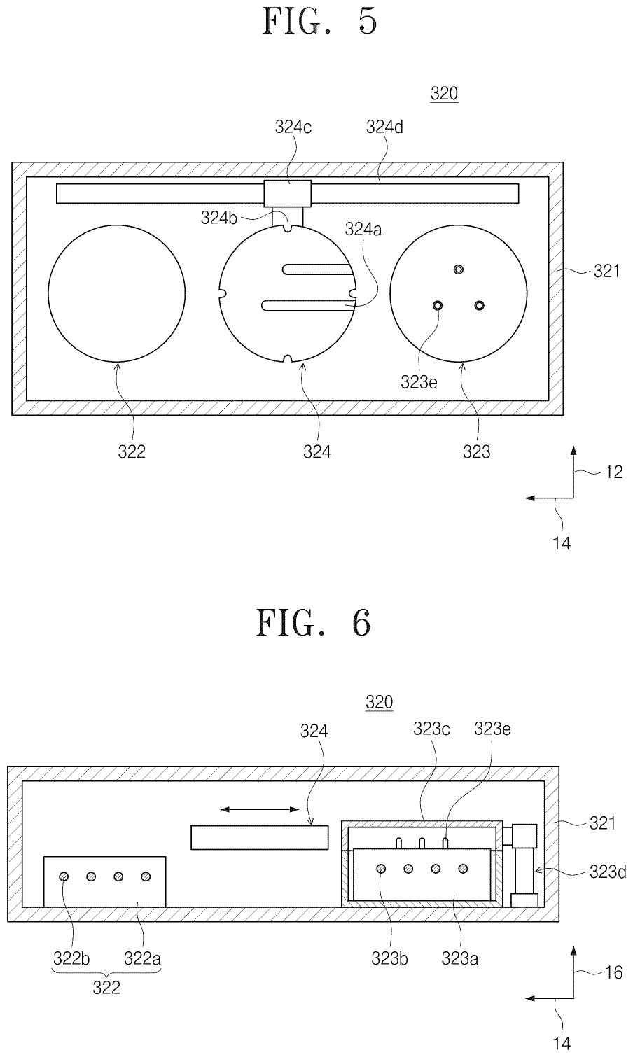

FIG. 5 is a top plan view schematically illustrating an example of the heat processing chamber of FIG. 3, and FIG. 6 is a front view of the heat processing chamber of FIG. 5. Referring to FIGS. 5 and 6, the heat processing chamber 320 includes a housing 321, a cooling member 322, a heating unit 323, and a transfer plate 324.

The housing 321 is provided in a generally rectangular parallelepiped shape. An entrance opening (not illustrated) through which the substrate W enters and exits is formed on a sidewall of the housing 321. The entrance opening may remain open. A door (not illustrated) may be provided to selectively open and close the entrance opening. The cooling member 322, the heating unit 323, and the transfer plate 324 are provided within the housing 321. The cooling member 322 and the heating unit 323 are arranged along the second direction 14. According to an example, the cooling member 322 may be positioned closer to the transfer chamber 350 than the heating unit 323.

The cooling member 322 has a cooling plate 322a. When viewed from above, the cooling plate 322a may have a substantially circular shape. A cooling member 322b is provided on the cooling plate 322a. According to an example, the cooling member 322b is formed inside the cooling plate 322a and may be provided as a flow path through which a cooling fluid flows.

The heating unit 323 includes a heating plate 323a, a cover 323c, and a heater 323b. When viewed from the top, the heating plate 323a has a generally circular shape. The heating plate 323a has a larger diameter than the substrate W. The heater 323b is installed on the heating plate 323a. The heater 323b may be provided as a heating resistor to which a current is applied. The heating plate 323a is provided with lift pins 323e that may be driven in the vertical direction along the third direction 16. The lift pin 323e receives the substrate W from a transfer means outside the heating unit 323 and puts the received substrate W down on the heating plate 323a, or lifts the substrate W from the heating plate 323a and hands over the substrate W to the transfer means outside the heating unit 323. According to an example, three lift pins 323e may be provided. The cover 323c is positioned above the heating plate 323a. The cover 323c is combined with the heating plate 323a to provide a heating space for heating the substrate W. The cover 323c is moved in the vertical direction by a driver 323d. When the cover 323c is moved in the third direction 16, the heating space is opened, and the transfer plate may load or unload the substrate W into or from the heating space.

The transfer plate 324 is generally provided with a disk shape and has a diameter corresponding to that of the substrate W. A notch 324b is formed at an edge of the transfer plate 324. The notch 324b may have a shape corresponding to that of a protrusion 354 formed in the hand 354 of the transfer robot 352 described above. Also, the notches 324b are provided by the number corresponding to that of the protrusions 354 formed in the hand 354, and are formed at positions corresponding to the protrusions 354. When the vertical positions of the hand 354 and the transfer plate 324 are changed at a position where the hand 354 and the transfer plate 324 are vertically aligned, the substrate W is transferred between the hand 354 and the transfer plate 324. The transfer plate 324 may be mounted on the guide rail 324d and may be moved along the guide rail 324d by a driver 324c. A plurality of slit-shaped guide grooves 324a is provided in the transfer plate 324. The guide groove 324a extends from the end of the transfer plate 324 to the inside of the transfer plate 324. The guide groove 324a is provided so that a longitudinal direction thereof is the second direction 14, and the guide grooves 324a are spaced apart from each other along the first direction 12. The guide groove 324a prevents the transfer plate 324 and the lift pin 323e from interfering with each other when the substrate W is taken over between the transfer plate 324 and the heating unit 323.

Cooling of the substrate W is performed in a state in which the transfer plate 324 on which the substrate W is placed is in contact with the cooling plate 322a. The transfer plate 324 is made of a material having high thermal conductivity so that heat transfer between the cooling plate 322a and the substrate W is well performed. According to an example, the transfer plate 324 may be made of a metal material.

The heating unit 323 provided to some of the heat processing chambers 320 may improve the adhesion rate of the photoresist on the substrate by supplying gas during heating of the substrate W. For example, the gas may be hexamethyldisilane (HMDS) gas.

A plurality of liquid processing chambers 360 is provided. Some of the liquid processing chambers 360 may be provided to be stacked on each other. The liquid processing chambers 360 are disposed on one side of the transfer chamber 350. The liquid processing chambers 360 are arranged side by side along the first direction 12. Some of the liquid processing chambers 360 are provided at positions adjacent to the index module 100. Hereinafter, the liquid processing chamber 360 positioned adjacent to the index module 100 is referred to as a front liquid processing chamber 362. Another part of the liquid processing chambers 360 is provided at a position adjacent to the interface module 600. Hereinafter, the liquid processing chamber 360 positioned adjacent to the interface module 600 is referred to as a rear liquid processing chamber 364.

The front liquid processing chamber 362 applies a first liquid on the substrate W, and the rear liquid processing chamber 364 applies a second liquid on the substrate W. The first liquid and the second liquid may be different types of liquids. According to the example, the first liquid is an antireflection film, and the second liquid is a photoresist. The photoresist may be applied on the substrate W to which the antireflection film is applied. Optionally, the first liquid may be a photoresist, and the second liquid may be an antireflection film. In this case, the antireflection film may be applied on the substrate W to which the photoresist is applied. Optionally, the first liquid and the second liquid are the same type of liquid, and all of them may be photoresist. According to an example, the photoresist film may be a metal-containing resist film.

The developing block 300b has the same structure as the applying block 300a, and the liquid processing chamber provided to the developing block 300b supplies a developer onto the substrate.

The interface module 600 connects the substrate processing apparatus 10 to the exposure module 700. The interface module 600 includes an interface frame 610, an additional process chamber 620, an interface buffer 630, and an interface robot 650.

A fan filter unit that forms descending airflow therein may be provided at an upper end of the interface frame 610. The additional process chamber 620, the interface buffer 630, and the interface robot 650 are disposed within the interface frame 610. The additional process chamber 620 may perform a predetermined additional process before the substrate W on which the process has been completed in the applying block 300a is loaded into the exposure module 700. Optionally, the additional process chamber 620 may perform a predetermined additional process before the substrate W on which the process has been completed in the exposure device 700 is loaded into the developing block 300b. According to an example, the additional process may be an edge exposure process for exposing an edge region of the substrate W, an upper surface cleaning process for cleaning the upper surface of the substrate W, or a lower surface cleaning process for cleaning the lower surface of the substrate W. A plurality of additional process chambers 620 may be provided, and they may be provided to be stacked on each other. All of the additional process chambers 620 may be provided to perform the same process. Optionally, some of the additional process chambers 620 may be provided to perform different processes.

The interface buffer 630 provides a space in which the substrate W transferred between the applying block 300a, the additional process chamber 620, the exposure module 700, and the developing block 300b temporarily stays during transfer. A plurality of interface buffers 630 may be provided, and a plurality of interface buffers 630 may be provided to be stacked on each other.

According to an example, the additional process chamber 620 may be disposed on one side based on an extension line of the transfer chamber 350 in the longitudinal direction and the interface buffer 630 may be disposed on the other side.

The interface robot 650 transfers the substrate W between the applying block 300a, the additional process chamber 620, the exposure device 700, and the developing block 300b. The interface robot 650 may have a transfer hand that transfers the substrate W. The interface robot 650 may be provided as one or a plurality of robots. According to an example, the interface robot 650 has a first robot 652 and a second robot 654. The first robot 652 may be provided to transfer the substrate W between a rear buffer 400b, the addition process chamber 620, and the interface buffer 630, the second robot 654 may be provided to transfer the substrate W between the interface buffer 630 and the exposure module 700, and the second robot 654 may be provided to transfer the substrate W between the interface buffer 630 and the developing block 300b.

Each of the first robot 652 and the second robot 654 includes a transfer hand on which the substrate W is placed, and the hand may be provided to be movable forward and backward, rotatable based on an axis parallel to the third direction 16, and movable along the third direction 16.

The hands of the index robot 132, the first robot 652, and the second robot 654 may all be provided in the same shape as the hand 354 of the transfer robot 352. Optionally, the hand of the robot that directly exchanges the substrate W with the transfer plate 324 of the heat processing chamber is provided in the same shape as the hand 354 of the transfer robot 352, and the hands of other robots may be provided in a different shape.

According to the exemplary embodiment, the transfer robot 352 provided in the applying block 300a and the developing block 300b may be provided to directly exchange the substrate W with the transfer plate 324 located in the heat processing chamber 320.

A plurality of buffer modules 400a and 400b is provided. A part of the buffer modules 400a and 400b is disposed between the index module 100 and the processing module 300. Hereinafter, these buffer modules are referred to as front buffers 400a. Another part of the buffer modules 400a and 400b is disposed between the processing module 300 and the interface module 600. Hereinafter, these buffer modules are referred to as rear buffers 400b. Each of the front buffers 400a and the rear buffers 400b temporarily stores a plurality of substrates W. The substrate W stored in the front buffer 400a is loaded or unloaded by the index robot 132 and the transfer robot 352. The substrate W stored in the rear buffer is loaded or unloaded by the transfer robot 352 and the interface robot 650.

Hereinafter, the buffer modules 400a and 400b are described based on the front buffer 400a. The front buffer 400a includes a frame 401, a buffer unit 410, a buffer robot 450, and a buffer chamber 500. The frame 401 may be provided in a rectangular parallelepiped shape having an empty inside. The frame 401 is disposed between the index module 100 and the processing module 300. The buffer unit 410, the buffer robot 450, and the buffer chamber 500 are provided inside the frame 401.

The buffer unit 410 is provided in an open structure. The buffer unit 410 is provided to horizontally accommodate the substrate W. The buffer unit 410 temporarily accommodates the substrate W transferred from the container F by the index robot 132. Also, the buffer unit 410 temporarily accommodates the substrate W transferred from the buffer robot 450. The buffer unit 410 is provided to accommodate a plurality of substrates W. The buffer unit 410 is provided to accommodate a plurality of substrates W at regular intervals. The shape and structure of the buffer unit 410 are not limited to a specific shape, and any shape and structure capable of performing the above functions may be sufficient.

The buffer robot 450 is located within the frame 401. The buffer robot 450 is provided on one side of the buffer unit 410. The buffer robot 450 transfers the substrate W between the buffer unit 410 and the buffer chamber 500. The buffer robot 450 includes a hand 451 and an arm 452. The hand 451 is fixed to and installed at the arm 452. The arm 452 is provided in an elastic structure. Accordingly, the buffer robot 450 may enter the buffer unit 410 or the buffer chamber 500 to load or unload the substrate W. Also, the arm 452 is provided to be movable in a vertical direction. Accordingly, the buffer robot 450 may move the hand 451 to a height corresponding to the stacked buffer units 410 and buffer chambers 500.

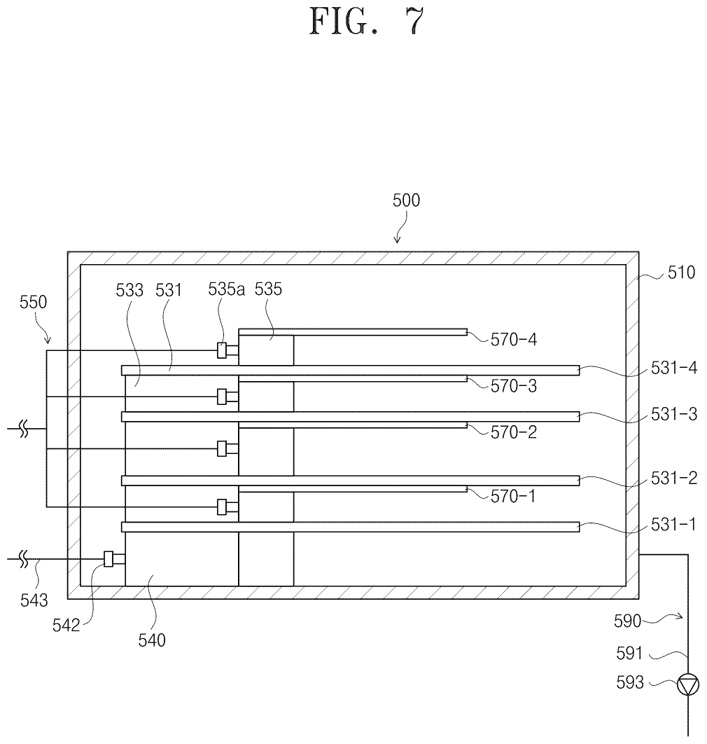

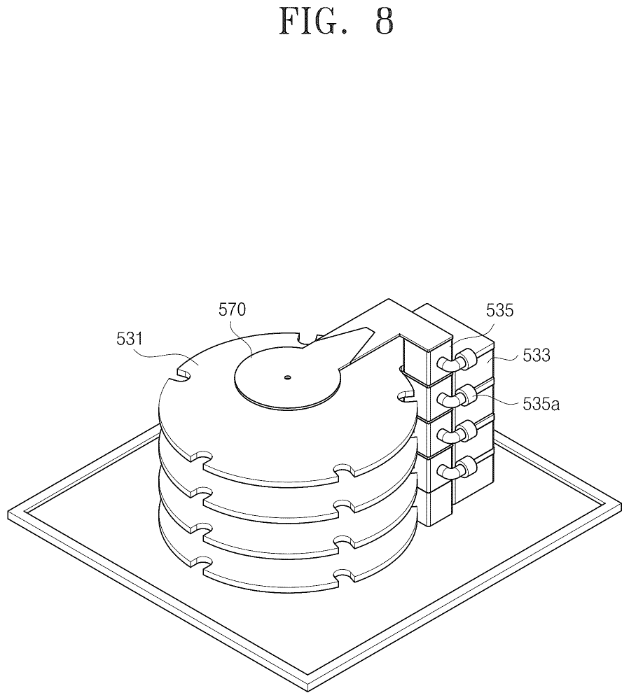

FIG. 7 is a cross-sectional view illustrating a cross-section of the buffer chamber according to the exemplary embodiment of the present invention, and FIG. 8 is a diagram schematically illustrating the support plate and the shower plate. Referring to FIGS. 7 and 8, the buffer chamber 500 is provided in a closed form. The buffer chamber 500 includes a housing 510, a support unit 530, a gas supply unit 550, a shower plate 570, and an exhaust unit 590.

The housing 510 provides an inner space. The housing 510 may be provided in a polyhedral shape. According to an example, the housing 510 may be provided in a hexahedral shape. An entrance opening (not illustrated) through which the substrate W enters and exits are formed at a sidewall of the housing 510. Also, a shutter (not illustrated) is provided to open and close the entrance opening. The entrance opening may be formed in the number and direction corresponding to the number and direction of robots entering the buffer chamber 500. According to an example, the entrance opening may be formed on a sidewall adjacent to the index robot 132, and on a sidewall adjacent to the buffer robot 450. However, the present invention is not limited thereto, and the entrance opening may be formed on a sidewall adjacent to the index robot 132 and the transfer robot 352. Also, the support unit 530 and the shower plate 570 are provided in the housing 510.

The support unit 530 supports the substrate W in the inner space. The support unit 530 includes a support plate 531, a first support block 533, and a second support block 535. A plurality of support plates 531 is provided. According to an example, four support plates 531 may be provided. Hereinafter, it is described as an example that four support plates 531-1, 531-2, 531-3, and 531-4 are provided. Each of the support plates 531 is disposed to be vertically stacked. The support plates 531 may be formed of aluminum. The first support block 533 is positioned between the support plates 531. The support plates 531 are positioned to be spaced apart from each other by the first support blocks 533. Each of the support plates 531 is fixed and coupled to the first support block 533. Each of the support plates 531 may have the same size. The support plates 531 may be provided to be spaced apart from each other at the same height. The shower plate 570 is installed on the second support block 535. The installation of the shower plate 570 is to be described later.

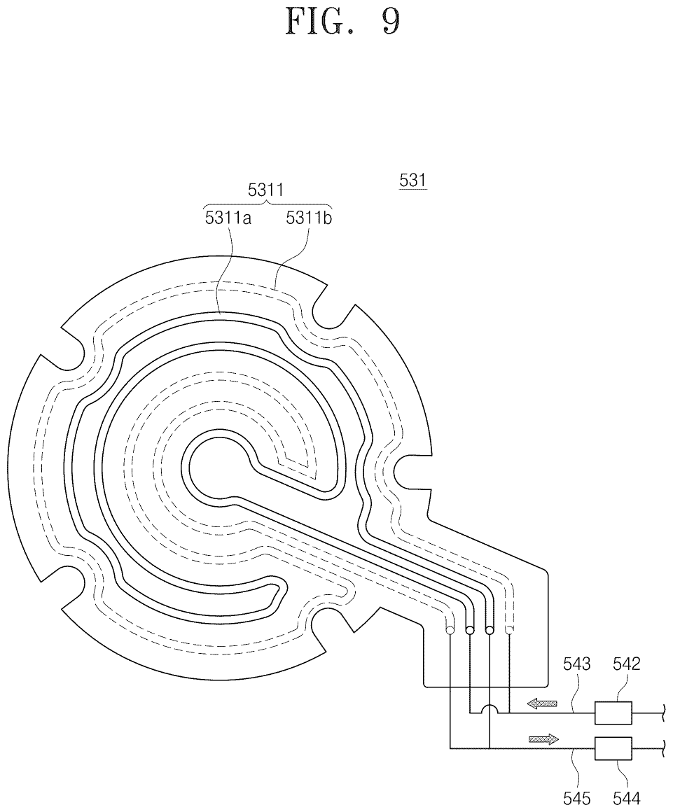

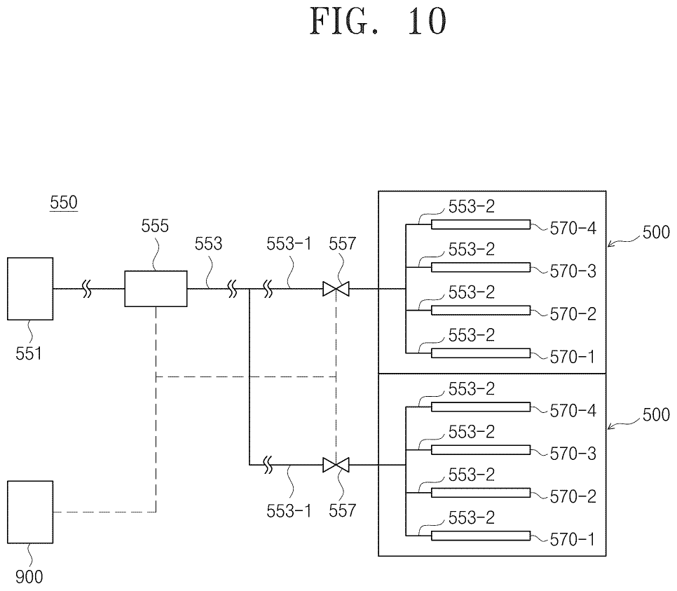

FIG. 9 is a diagram schematically illustrating a support plate according to an exemplary embodiment of the present invention. Referring to FIG. 9, a cooling flow path 5311 through which a cooling fluid flows is formed in the support plate 531. The cooling flow path 5311 is formed inside the support plate 531. The cooling flow path 5311 is provided as a passage through which a cooling fluid flows. A plurality of cooling flow paths 5311 is provided. The cooling flow path 5311 includes a first flow path 5311a through which a cooling fluid flows in an outward direction and a second flow path 5311b through which a cooling fluid flows in an inward direction opposite to the outward direction. The outward direction may be a direction that flows from a central region to an edge region of the support plate 531. The inward direction may be a direction through which the cooling fluid flows from an edge region of the support plate 531 toward the central region. The cooling fluid may be provided as cooling water. The first flow path 5311a and the second flow path 5311b are provided adjacent to each other. The first flow path 5311a and the second flow path 5311b may be provided on the same plane in the support plate 531. Each of the first flow path 5311a and the second flow path 5311b may be spirally arranged.

Referring back to FIGS. 7 and 8, the first support block 533 is positioned between the support plates 531. The first support block 533 allows adjacent support plates 531 to be spaced apart from each other in the vertical direction. The first support block 533 may be provided in a substantially rectangular parallelepiped shape. Also, a plurality of first support blocks 533 may be provided. The first support blocks 533 are provided to be stacked on each other.

The first base block 540 supports the lowermost support plate 531. The first base block 540 is provided with an inlet port 542, an outlet port 544, a cooling fluid supply flow path 543, and a cooling fluid recovery flow path 545. The inlet port 542 receives a cooling fluid from the outside and supplies the cooling fluid to the cooling fluid supply flow path 543. The inlet port 542 is located on one side of the first base block 540. The outlet port 544 discharges a cooling fluid from the cooling fluid recovery flow path 545 to the outside. The outlet port 544 is located on one side of the first base block 540. Sides of the first base block 540 where the inlet port 542 and the outlet port 544 are provided may be perpendicular to each other. The inlet port 542 and the outlet port 544 may be provided at the same height from the support plate 534.

The cooling fluid supply flow path 543 is provided inside the first base block 540 and the first support block 533. The cooling fluid supply flow path 543 allows the cooling fluid received from the inlet port 542 to be supplied to the support plate 531. One side of the cooling fluid supply flow path 543 is connected to the inlet port 542, and the other side is branched and connected to the inlet ports of the first flow path 5311a and the second flow path 5311b formed inside each of the support plates 531.

The cooling fluid recovery flow path 545 is provided inside the first base block 540 and the first support block 533. The cooling fluid recovery flow path 545 allows the cooling fluid discharged from the support plate 531 to be discharged to the outlet port 544. One side of the cooling fluid recovery flow path 545 is connected to the outlets of the first flow path 5311a and the second flow path 5311b formed inside each of the support plates 531, and the other side thereof is connected to the outlet port 544. The cooling fluid recovery flow path 545 and the cooling fluid supply flow path 543 may be provided parallel to each other.

FIG. 10 is a diagram illustrating the gas supply unit according to the exemplary embodiment of the present invention. Referring to FIG. 10, the gas supply unit 550 supplies gas to the shower plate 570. The gas supply unit 550 includes a gas supply source 551, a gas supply line 553, a dehumidification processing unit 555, and a valve 557. The gas supply source 551 stores and supplies gas. The gas may be low humidity gas. The gas may be gas having a humidity lower than that in the atmospheres of the index module 100 and the processing module 300. According to an example, the humidity of the low humidity gas may be 0.1% or less.

The gas supply line 553 connects the shower plate 570 to the gas supply source 551. The gas supply line 553 may be connected to the shower plate 570 through a supply port 535a formed in the second support block 535. Accordingly, the gas supply line 553 may provide a path through which gas moves to the shower plate 570. When a plurality of shower plates 570 is provided, the gas supply line 553 may be branched by a number corresponding to the number of shower plates 570. In addition, when a plurality of buffer chambers 500 is provided, the gas supply line 553 may be branched by a number corresponding to the number of buffer chambers 500. According to an example, when two buffer chambers 500 and four shower plates 570 are provided, the gas supply line 553 may be branched into two upstream lines 553-1 and each branch line may be branched into four downstream lines 553-2 again. A valve 557 may be installed in each upstream line 553-1. The valve 557 may be a flow rate control valve. Each valve 557 may be independently controlled. Accordingly, a consumption amount of the gas may be optimized by adjusting a flow rate of the gas supplied to the buffer chamber 500.

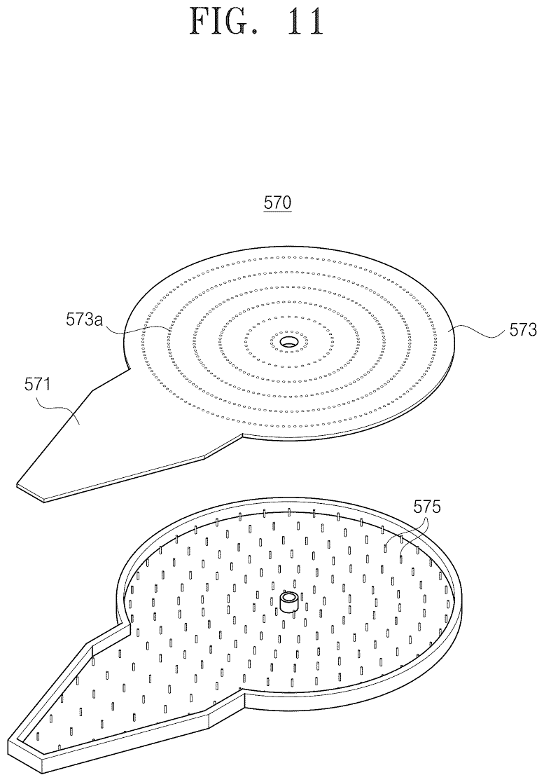

The shower plate 570 injects gas onto the substrate W supported on the upper surface of the support plate 531. FIG. 11 is a diagram illustrating a shape of the shower plate according to the exemplary embodiment of the present invention. However, FIG. 11 illustrates a state in which the shower plate is turned upside down for the sake of description and understanding. Referring to FIG. 11, the shower plate 570 includes a connection part 571, an injection part 573, and a guide member 575.

The connection part 571 and the injection part 573 are integrally formed. In addition, the inner spaces of the connection part 571 and the injection part 573 are formed to spatially communicate with each other.

The connection part 571 connects the gas supply unit 550 and the injection part 573. The connection part 571 has a space in which gas flows. The gas supplied to the connection part 571 flows toward the injection part 573. The connection part 571 is provided in a size and shape in which interference does not occur with the index robot 132, the transfer robot 352, and the buffer robot 450 entering the buffer chamber 500.

The injection part 573 injects gas onto the substrate W. The injection part 573 has a space in which gas flows. The injection part 573 is provided in a circular shape. The injection part 573 is provided in a size in which interference does not occur with the index robot 132, the transfer robot 352, and the buffer robot 450 entering the buffer chamber 500. According to an example, the diameter of the injection part 573 may be provided smaller than the diameter of the substrate W. Also, the diameter of the injection part 573 may be provided smaller than the diameter of the support plate 531.

The guide member 575 is provided in the shower plate 570. The guide member 575 is provided in the connection part 571 and the injection part 573. Also, a plurality of guide members 575 is provided. The guide members 575 may be disposed at regular intervals. According to an example, the guide member 575 may be a cylindrical guide pin. The guide pins may be arranged along the circumferential direction of the injection part 573. The guide pins may be arranged to form a plurality of concentric circles with respect to the center of the injection part 573. The guide member 575 guides the flow of gas supplied to the shower plate 570. The gas is uniformly diffused into the shower plate 570 by the guide member 575. Even if the gas is supplied to the side of the injection part 573, the guide member 575 may uniformly supply the gas onto the substrate W.

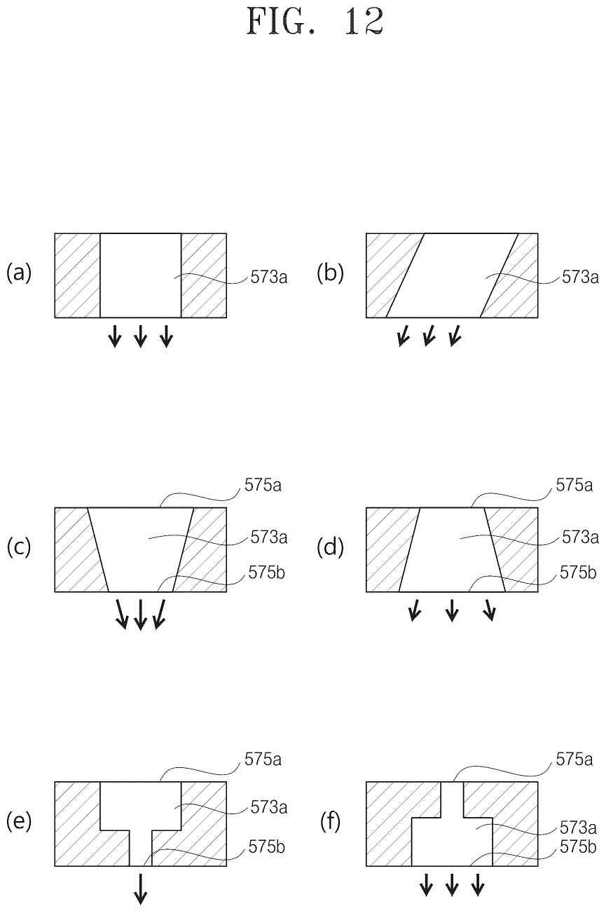

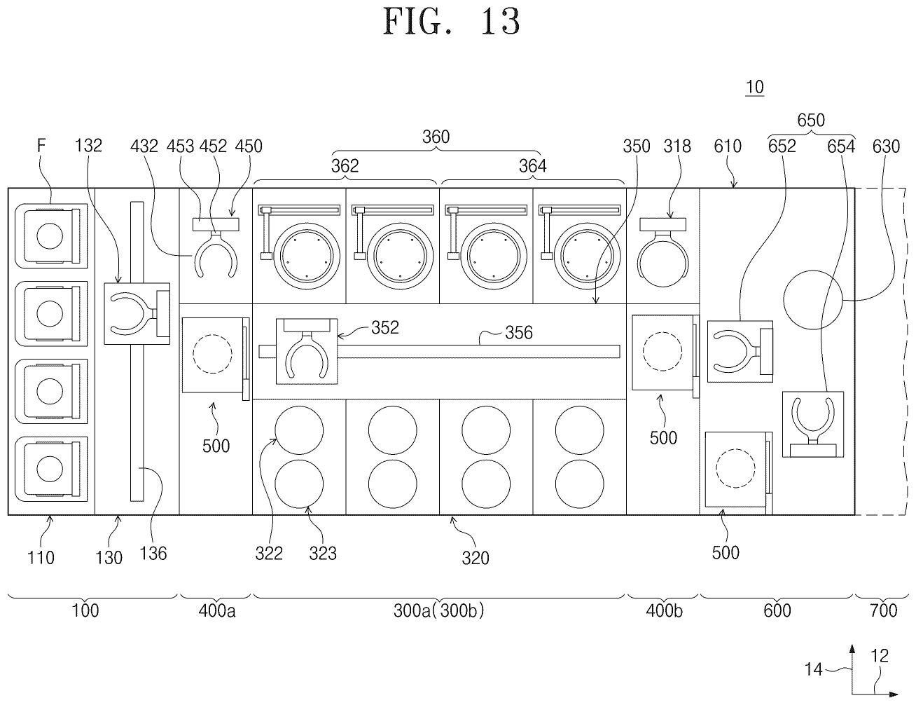

A plurality of injection holes 573a is formed on the bottom surface of the injection part 573. The injection hole 573a may be provided in various shapes. FIG. 12 is a diagram illustrating various shapes of the injection hole. Referring to FIG. 12, the injection hole 573a may have various shapes. The injection angle and injection speed of the gas supplied to the shower plate 570 may vary according to the shape of the injection hole 573a. Referring to (a) of FIG. 12, the injection hole 573a may be provided vertically. Accordingly, the gas may be injected vertically with respect to the substrate W. Also, referring to (b) of FIG. 12, the injection hole 573a may be provided to be inclined. Accordingly, the gas may be injected obliquely with respect to the substrate W, and may be injected up to an edge region of the substrate W. When viewed from above, the injection hole 573a may have different areas of the upper surface 577a and the lower surface 577b. According to an example, the injection port 573a may be provided in a tapered shape as in (c) of FIG. 12, or may be provided in a stepped shape as in (d) of FIG. 12. When the area of the upper surface 577a is larger than the area of the lower surface 577b, the flow rate of the gas supplied to the substrate W may be increased. When the area of the upper surface 577a is smaller than the area of the lower surface 577b, the flow rate of the gas supplied to the substrate W may be decreased. A plurality of injection holes 573a may be formed in various ways depending on conditions required for the substrate W to be processed. According to an example, the injection hole 573a may be provided in a vertical shape in the central region of the injection part 573, but may be provided in an inclined shape in the edge region. In addition, the injection hole 573a may be provided in a vertical shape in the central region of the injection part 573, and may be provided in a shape in which the inclination angle increases in the radial direction of the injection part 573. Accordingly, even when the diameter of the injection part 573 is provided smaller than that of the substrate W, the gas may be uniformly injected to the substrate W.

Referring back to FIGS. 7 and 8, a plurality of second support blocks 535 is provided. The second support blocks 535 are provided in a number corresponding to the number of shower plates 570. A plurality of second support blocks 535 has a stacked structure. Accordingly, the shower plate 570 is also provided in a stacked structure. The shower plate 570 is installed on an upper end of the second support block 535. Also, the shower plate 570 is located on a lower surface of the support plate 531. The shower plate 570 is located on the support plate 531 so as to be adjacent to an upper portion. Hereinafter, the present invention has been described based on the case where four support plates 531 and four shower plates 570 are provided and installed as an example. The support plate 531 is provided so that a first support plate 531-1, a second support plate 531-2, a third support plate 531-3, and a fourth support plate 531-4 are stacked, and the shower plates 570-1, 570-2, 570-3, and 570-4 are located above the support plates 531-1, 531-2, 531-3, and 531-4, respectively. The first shower plate 570-1 is provided so as to be adjacent to a lower surface of the second support plate 531-2. The second shower plate 570-2 is provided to be adjacent to a lower surface of the third support plate 531-3. The third shower plate 570-3 is provided to be adjacent to a lower surface of the fourth support plate 531-4.

The exhaust unit 590 exhausts the inner space. The exhaust unit 590 includes an exhaust line 591 connected to the inner space. The exhaust line 591 may be connected to the inner space through an exhaust hole formed in a side of the buffer chamber 500. A pump 593 may be installed in the exhaust line 591 and the pump 593 may depressurize the inner space of the housing 510 and exhaust the inner space.

The controller 900 controls the substrate processing apparatus 10 of the present invention. The configuration, storage, and management of the controller are feasible in the form of hardware, software, or a combination of hardware and software. The file data and/or the software constituting the controller may be stored in, for example, a volatile or nonvolatile storage device, such as a Read Only Memory (ROM) regardless of removable or rewriteable performance, or a memory, such as a Random Access Memory (RAM), a memory chip, a device, or a storage medium, such as a Compact Disk (CD), a Digital Version Disc (DVD), a magnetic disk, or a magnetic tape, capable of optically or magnetically recording data and simultaneously being readable by machine (for example, a computer).

The rear buffer 400b temporarily stores the substrates W on which the process has been performed before being moved to the exposure module 700. The rear buffer 400b is provided substantially the same as the front buffer 400a.

Hereinafter, a process of processing the substrate W with low humidity in the buffer chamber 500 in the substrate processing apparatus 10 of the present invention will be described. The configurations performing respective processes may be driven by the controller. The controller may independently control each configuration.

When the substrate W is transferred from the container F to the processing module 300, the substrate W may pass through the buffer chamber 500. Furthermore, the substrate W may be processed in the heat processing chamber 320 or the liquid processing chamber 360 and may wait in the buffer chamber 500. While the substrate W waits in the buffer chamber 500, the valve 557 may be controlled to supply gas to the buffer chamber 500. The gas is uniformly injected onto the substrate W by the shower plate 570. Accordingly, the gas atmosphere on the substrate W is uniformly formed. Furthermore, the inside of the buffer chamber 500 is converted into the supplied gas atmosphere.

Since the metal-containing resist applied on the substrate W is vulnerable to moisture, it is necessary to maintain the atmosphere around the substrate W at a low humidity. According to the exemplary embodiment of the present disclosure, since the buffer chamber W is provided in a closed structure, the atmosphere of the inner space may be controlled. In particular, when gas of low humidity is supplied to the inner space, the inner space may be maintained at a low humidity. The reaction between moisture and the metal-containing resist may be suppressed, thereby preventing damage to the metal-containing resist or generation of impurities.

In addition, according to the exemplary embodiment of the present invention, even though the plurality of robots 132, 352, and 450 enters the buffer chamber 500 at the same time, the transfer efficiency of the substrate W may be improved because the interference between the shower plate 570 and the robots 132, 352, and 450 is minimized.

In addition, according to the exemplary embodiment of the present invention, even though the shower plate 570 is provided smaller than the substrate W, the uniformity in the substrate W may be improved by uniformly injecting the gas onto the substrate W.

Further, according to the exemplary embodiment of the present invention, the shower plate 570 is provided for each support plate 531. Accordingly, since the substrate W may be processed in the same atmosphere, uniformity between a plurality of substrates W may be improved.

In addition, according to the exemplary embodiment of the present invention, the shower plate 570 is installed adjacent to the lower part of the support plate 531, so that the space occupied by the buffer chamber 500 may be efficiently utilized.

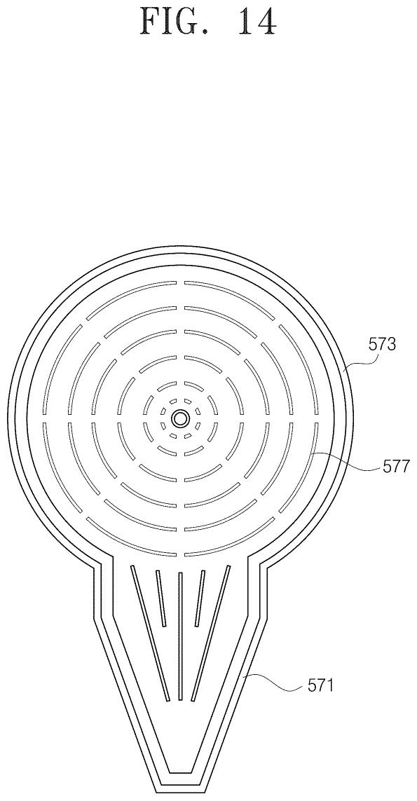

In the above-described example, the present invention has been described based on the case where the guide member 575 is a guide pin as an example. However, the present invention is not limited thereto, and the guide member 575 may be a guide wall as illustrated in FIG. 14.

Furthermore, in the above-described example, the present invention has been described based on the case where the buffer chamber 500 is provided only in the front buffer 400a as an example. However, the present invention is not limited thereto, and the buffer chamber 500 may also be provided to the rear buffer 400b and/or the interface module 600 as illustrated in FIG. 13. When the buffer chamber 500 is provided to the rear buffer 400b, the buffer chamber 500 may be stacked with the buffer unit 410 provided to the rear buffer 400b. Furthermore, when the buffer chamber 500 is provided to the interface module 600, the buffer chamber 500 may be stacked with the additional process chamber 620 and/or the interface buffer 630.

The foregoing detailed description illustrates the present invention. Further, the above content shows and describes the exemplary embodiment of the present invention, and the present invention may be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

What is claimed is:

1. An apparatus for processing a substrate, the apparatus comprising:
a first module;
a second module; and
a buffer chamber disposed between the first module and the second module and temporarily storing a substrate transferred between the first module and the second module,
wherein the transfer chamber includes:
a housing providing an inner space;
a support unit including a plurality of support plates supporting the substrate in the inner space;
a plurality of shower plates having an injection hole for injecting the gas to the substrate supported by the support unit; and
a gas supply unit for supplying the gas to the shower plate, and
the support plates are provided in a stacked structure, and
each of the shower plates is provided to correspond to each of the support plates.

2. The apparatus of claim 1, wherein the first module is an index module,
the second module is a processing module, and
the index module includes:
a load port on which a container in which the substrate is accommodated is placed; and
an index robot for transferring the substrate from the container placed on the load port to the processing module, and accommodating the substrate completely processed in the processing module in the container placed on the load port, and
the processing module includes:
a process chamber for processing the substrate; and
a transfer chamber including a transfer robot that loads the substrate into the process chamber or unloads a substrate from the process chamber.

3. The apparatus of claim 2, wherein the shower plate includes:
an injection part for injecting the gas into the substrate supported on the support plate; and
a connection part connecting the gas supply unit and the injection part, and
the connection part is provided on the side of the injection part.

4. The apparatus of claim 3, wherein the shower plate further includes a guide member provided inside the connection part and the injection part, and
the guide member guides flow of the gas so that the gas injected into the connection part is uniformly diffused toward the injection part.

5. The apparatus of claim 4, wherein the guide member includes a plurality of guide pins, and
the guide pins are arranged to be spaced apart from each other, and are combined with each other to form a concentric circle.

6. The apparatus of claim 4, wherein the guide member includes a plurality of guide walls, and
the guide walls are arranged to be spaced apart from each other, and are combined with each other to form a concentric circle.

7. The apparatus of claim 2, wherein the shower plate includes a first shower plate and a second shower plate,
the support plate includes a first support plate and a second support plate,
the first support plate, the first shower plate, the second support plate, and the second shower plate are stacked in this order, and
the first shower plate is provided to be adjacent to a lower portion of the second support plate.

8. The apparatus of claim 3, wherein a diameter of the injection part is smaller than a diameter of the support plate.

9. The apparatus of claim 7, wherein the injection holes are provided in plural, and
among the injection holes, the injection hole in a central region of the shower plate is vertically formed, and
among the injection holes, the injection hole in an edge region of the shower plate is formed to be inclined.

10. The apparatus of claim 2, wherein the plurality of buffer chambers is provided to be stacked,
the gas supply unit includes a valve that adjusts a flow rate of the gas supplied to the buffer chamber, and
the apparatus includes a controller that independently controls the valve.

11. The apparatus of claim 2, wherein the gas has a lower humidity than a surrounding atmosphere of the index robot or the transfer robot.

12. A buffer chamber for temporarily storing a substrate, the buffer chamber comprising:
a housing providing an inner space;
a support unit including a plurality of support plates supporting a substrate in the inner space;
a plurality of shower plates having a plurality of injection holes for injecting the gas to the substrate supported by the support unit; and
a gas supply unit for supplying the gas to the shower plate, and
the support plates are provided in a stacked structure, and
each of the shower plates is provided to correspond to each of the support plates.

13. The buffer chamber of claim 12, wherein the shower plate further includes:
a connection part into which the gas is injected;
an injection part formed to spatially communicate with the connection part; and
a guide member for guiding a flow of the gas so that the gas injected into the connection part is uniformly diffused inside the injection part,
the connection part is provided on a side of the injection part, and
a plurality of guide members is provided inside the connection part and the injection part, and are spaced apart from each other and combined with each other to form a concentric circle.

14. The buffer chamber of claim 13, wherein the shower plate includes a first shower plate and a second shower plate,
the support plate includes a first support plate and a second support plate,
the first support plate, the first shower plate, the second support plate, and the second shower plate are stacked in this order, and
the first shower plate is provided to be adjacent to a lower portion of the second support plate.

15. The buffer chamber of claim 12, wherein among the injection holes, the injection hole in a central region of the shower plate is vertically formed, and
among the injection holes, the injection hole in an edge region of the shower plate is formed to be inclined.

16. The buffer chamber of claim 13, wherein the plurality of shower plates is installed under the support plate, which is adjacent to an upper side, and
a diameter of the injection part is smaller than a diameter of the support plate.

17. The buffer chamber of claim 12, wherein the gas has a lower humidity than a surrounding atmosphere of the index robot or the transfer robot.

18. An apparatus for processing a substrate, the apparatus comprising:
an index module for unloading a substrate from a container in which the substrate is accommodated or loads the substrate into the container;
a processing module for processing a substrate; and
a buffer chamber for temporarily storing a substrate,
wherein the index module includes:
a load port on which the container in which the substrate is accommodated is placed; and
an index robot for transferring the substrate from the container placed on the load port to the processing module, and accommodating the substrate completely processed in the processing module in the container placed on the load port, and
the processing module includes:
a process chamber for processing the substrate; and
a transfer chamber including a transfer robot that loads the substrate into the process chamber or unloads the substrate from the process chamber,
the buffer chamber includes:
a housing providing an inner space;
a support unit for supporting the substrate in the inner space;
a plurality of shower plates having a plurality of injection holes for injecting gas to the substrate supported by the support unit; and
a gas supply unit for supplying the gas to the shower plate, and
the support unit includes a plurality of support plates that supports the substrate and is provided in a stacked structure,
the gas has a lower humidity than a surrounding atmosphere of the index robot or the transfer robot,
the shower plate is provided to correspond to each support plate, and includes:
an injection part for injecting the gas into the substrate supported on the support plate; and
a connection part connecting the gas supply unit and the injection part; and
a plurality of guide members installed inside the connection part and the injection part and arranged to have a concentric pattern based on a center of the injection part,
the connection part is provided on a side of the injection part, and
a diameter of the injection part is smaller than a diameter of the support plate.

19. The apparatus of claim 18, wherein the shower plate includes a first shower plate and a second shower plate,
the support plate includes a first support plate and a second support plate,
the first support plate, the first shower plate, the second support plate, and the second shower plate are stacked in this order, and
the first shower plate is provided to be adjacent to a lower portion of the second support plate.

20. The apparatus of claim 19, wherein the plurality of buffer chambers is provided to be stacked,
the gas supply unit includes a valve that adjusts a flow rate of the gas supplied to the buffer chamber, and
the apparatus includes a controller that independently controls the valve.
